(19) United States
(12) Patent Application Publication
(10) Pub. No.: US 2025/0381883 A1
(43) Pub. Date: Dec. 18, 2025

(54) ELECTRIFIED VEHICLE AND BATTERY CONTROL METHOD THEREOF

(71) Applicants: HYUNDAI MOTOR COMPANY, Seoul (KR); KIA CORPORATION, Seoul (KR)

(72) Inventors: Ki Seung Baek, Hwaseong-si (KR); Hyun Soo Park, Hwaseong-si (KR); Tae Jun Kang, Hwaseong-si (KR); Sung Il Lee, Hwaseong-si (KR); Deok Keun Shin, Hwaseong-si (KR); Jin Cheol Shin, Hwaseong-si (KR)

(73) Assignees: HYUNDAI MOTOR COMPANY, Seoul (KR); KIA CORPORATION, Seoul (KR)

(21) Appl. No.: 18/977,378

(22) Filed: Dec. 11, 2024

(30) Foreign Application Priority Data
Jun. 17, 2024 (KR) 10-2024-0078446

(51) Int. Cl. B60L 58/13; G01R 31/371; G01R 31/374; H01M 10/42; H01M 10/48

(52) U.S. Cl. CPC B60L 58/13; G01R 31/371; G01R 31/374; H01M 10/425; H01M 10/486; B60L 2240/545; H01M 2010/4271

(57) ABSTRACT

Proposed are an electrified vehicle in which a real state of charge (SOC) of a battery is converted into a display SOC based on conditions such as a change in temperature of the battery, whether the battery is charged by an external power source, and a battery control method of the electrified vehicle. Particularly, a lower limit reference point, an upper limit reference point, and an inflection point are determined, a corresponding relationship between a real SOC and a display SOC is determined based on the lower limit reference point, the upper limit reference point, and the inflection point, and the real SOC is capable of being converted into the display SOC based on the corresponding relationship.

### CROSS-REFERENCE TO RELATED APPLICATION

The present application claims priority to Korean Patent Application No. 10-2024-0078446, filed Jun. 17, 2024, the entire contents of which are incorporated herein for all purposes by this reference.

### TECHNICAL FIELD

The present disclosure relates to an electrified vehicle in which a real state of charge (SOC) of a battery is converted into a display SOC based on conditions such as a change in temperature of the battery, whether the battery is charged by an external power source, and relates to a battery control method of the electrified vehicle.

### BACKGROUND

An electric vehicle and a hybrid vehicle are electrified vehicles provided with an electric motor (a driving motor) as a driving source. One of the components of such an eco-friendly vehicle is a battery.

Generally, for safety reasons, the battery should have a safety margin, should not be charged to 100% of the real state of charge (SOC) of the battery when the battery is used, and should not be used by discharging the battery to 0%. For example, the battery may be used between a preset lower limit value (for example, 5%) and a preset upper limit value (for example, 97%). In such a case, the SOC of the battery when the battery is fully charged is the preset upper limit value and is not 100%. However, when the SOC is displayed to a driver as it is, the driver may have a complaint that the battery is not fully charged. In addition, there is a case in which the battery is not fully charged or discharged due to characteristics of the battery in a low temperature state.

In the case described above, in order to prevent the driver's complaint, a plan to expand a range of the display SOC output through an output device beyond a real range may be considered.

The foregoing is intended merely to aid in the understanding of the background of the present disclosure, and is not intended to mean that the present disclosure falls within the purview of the related art that is already known to those skilled in the art.

### SUMMARY

An objective of the present disclosure is to provide an electrified vehicle in which a real state of charge (SOC) of a battery is converted into a display SOC based on a change in conditions such as a change in temperature of the battery, and is to provide a battery control method of the electrified vehicle.

The technical problems to be solved by the present disclosure are not limited to the above-mentioned problems, and other problems which are not mentioned will be clearly understood by those skilled in the art from the following description.

In order to achieve the objective of the present disclosure, according to an aspect of the present disclosure, provided is a battery control method including determining a lower limit reference point based on a temperature of a battery or a real State Of Charge (SOC) of the battery, the lower limit reference point being defined by a preset display SOC lower limit value and a real SOC lower limit value corresponding to the preset display SOC lower limit value, determining an upper limit reference point defined by a preset display SOC upper limit value and a real SOC upper limit value corresponding to the preset display SOC upper limit value, and determining a corresponding relationship based on the lower limit reference point and the upper limit reference point and converting the real SOC to a display SOC.

For example, the determining the lower limit reference point may include determining the lower limit reference point by determining any one of a plurality of real SOC lower limit values corresponding to the temperature of the battery as the real SOC lower limit value, the plurality of real SOC lower limit values being preset so as to correspond to different temperatures or temperature ranges.

For example, the determining the lower limit reference point may include determining the real SOC lower limit value as a first real SOC lower limit value when the temperature of the battery is equal to or more than a preset first temperature, as a second real SOC lower limit value when the temperature of the battery is equal to or less than the first temperature and equal to or more than a second temperature, and as a third real SOC lower limit value when the temperature of the battery is equal to or less than the second temperature. Furthermore, the first temperature may be higher than the second temperature.

For example, the battery control method may further include determining an inflection point based on a change in temperature of the battery and whether the battery is charged by an external power source. Furthermore, the inflection point may be defined by the real SOC and the display SOC of the battery at the time when the inflection point is determined, and the corresponding relationship may be changed before and after the inflection point.

For example, the determining the inflection point may include determining the inflection point at the time when the temperature of the battery is changed and the real SOC lower limit value is changed and at the time when charging of the battery by the external power source is started or ended.

For example, the determining the inflection point may include deleting a stored inflection point when the real SOC of the battery is equal to or less than the real SOC lower limit value of the lower limit reference point or when the real SOC of the battery is equal to or more than the real SOC upper limit value of the upper limit reference point.

For example, the converting the real SOC to the display SOC may include determining the corresponding relationship based on the lower limit reference point defined by the display SOC lower limit value and the corresponding real SOC lower limit value and based on the upper limit reference point defined by the display SOC upper limit value and the corresponding real SOC upper limit value.

For example, the converting the real SOC to the display SOC may include determining a first corresponding relationship through equation 1. [Equation 1] is Y_{V}=(Y_{H}−Y_{L}/X_{H}−X_{L})×(X_{V}−X_{L})+Y_{L}. YH refers to the display SOC upper limit value of the upper limit reference point, XH refers to the real SOC upper limit value of the upper limit reference point, YL refers to the display SOC lower limit value of the lower limit reference point, XL refers to the real SOC lower limit value of the lower limit reference point, YV refers to the display SOC that is converted, and XV refers to the real SOC of the battery.

For example, the converting the real SOC to the display SOC may include determining the corresponding relationship based on the lower limit reference point defined by the display SOC lower limit value and the corresponding real SOC lower limit value, the upper limit reference point defined by the display SOC upper limit value and the corresponding real SOC upper limit value, and the inflection point.

For example, the converting the real SOC to the display SOC may include converting the real SOC of the battery to the display SOC through a second corresponding relationship when the real SOC of the battery is equal to or less than the real SOC at the inflection point, and through a third corresponding relationship when the real SOC of the battery is equal to or more than the real SOC at the inflection point.

For example, the converting the real SOC to the display SOC may include determining the second corresponding relationship through equation 2. [Equation 2] is Y_{V}=(Y_{Z}−Y_{L}/X_{Z}−X_{L})×(X_{V}−X_{L})+Y_{L}. YL refers to the display SOC lower limit value of the lower limit reference point, XL refers to the real SOC lower limit value of the lower limit reference point, YZ refers to the display SOC at the inflection point, XZ refers to the real SOC at the inflection point, YV refers to the display SOC that is converted, and XV refers to the real SOC of the battery.

For example, the converting the real SOC to the display SOC may include determining the third corresponding relationship through equation 3. [Equation 3] is Y_{V}=(Y_{H}−Y_{Z}/X_{H}−X_{Z})×(X_{V}−X_{H})+Y_{H}. YH refers to the display SOC upper limit value of the upper limit reference point, XH refers to the real SOC upper limit value of the upper limit reference point, YZ refers to the display SOC at the inflection point, XZ refers to the real SOC at the inflection point, YV refers to the display SOC that is converted, and XV refers to the real SOC of the battery.

For example, the battery control method may further include outputting the display SOC that is determined.

In order to achieve the objective of the present disclosure, according to an aspect of the present disclosure, provided is a vehicle including a battery configured to store electric power required for driving the vehicle, a battery management system (BMS) configured to acquire status information of the battery, such as voltage, current, SOC, temperature, and usable power, and a controller configured to determine a lower limit reference point based on a temperature of the battery and a real state of charge (SOC) of the battery in which the lower limit reference point is defined by a preset display SOC lower limit value and a real SOC lower limit value corresponding to the preset display SOC lower limit value, configured to determine an upper limit reference point defined by a preset display SOC upper limit value and a real SOC upper limit value corresponding to the preset display SOC upper limit value, configured to determine a corresponding relationship based on the lower limit reference point and the upper limit reference point, and configured to convert the real SOC into a display SOC.

For example, the controller may be configured to determine the corresponding relationship based on the lower limit reference point defined by the display SOC lower limit value and the corresponding real SOC lower limit value and based on the upper limit reference point defined by the display SOC upper limit value and the corresponding real SOC upper limit value.

For example, the controller may be configured to determine an inflection point based on a change in temperature of the battery and whether the battery is charged by an external power source, the inflection point may be defined by the real SOC and the display SOC of the battery at the time when the inflection point is determined, and the corresponding relationship may be changed before and after the inflection point.

For example, the controller may be configured to determine the corresponding relationship based on the lower limit reference point defined by the display SOC lower limit value and the corresponding real SOC lower limit value, the upper limit reference point defined by the display SOC upper limit value and the corresponding real SOC upper limit value, and the inflection point.

For example, the vehicle may further include an output device configured to output the display SOC.

For example, the output device may include at least one of a cluster, a Head-Up Display (HUD), a display device, and a speaker.

In the present disclosure, the electrified vehicle in which the real state of charge (SOC) of the battery is converted into the display SOC based on conditions such as a change in temperature of the battery and whether the battery is charged by the external power source, and a battery control method of the electrified vehicle may be provided.

Particularly, the lower limit reference point, the upper limit reference point, and the inflection point are determined, a corresponding relationship between the real SOC and the display SOC is determined based on the lower limit reference point, the upper limit reference point, and the inflection point, and the real SOC is capable of being converted into the display SOC based on the corresponding relationship.

The effects that can be obtained from the present disclosure are not limited to the above-mentioned effects, and other effects not mentioned herein will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating an example of a configuration of an electrified vehicle according to an embodiment of the present disclosure;

FIG. 2 is a flowchart illustrating a battery control method of the electrified vehicle according to an embodiment of the present disclosure;

FIG. 3 is a flowchart specifically illustrating a process of converting a real state of charge (SOC) into a display SOC according to an embodiment of the present disclosure; and

FIGS. 4, 5, 6, and 7 are graphs showing examples of converting the real SOC into the display SOC according to an embodiment of the present disclosure.

### DETAILED DESCRIPTION

Hereinafter, exemplary embodiments disclosed in the present specification will be described in detail with reference to the accompanying drawings. In the present specification, the same or similar components will be denoted by the same or similar reference numerals, and a repeated description thereof will be omitted. In the following description, the expressions “module” and “part” contained in terms of constituent elements to be described will be selected or used together in consideration only of the convenience of writing the following specification, and the expressions “module” and “part” do not necessarily have different meanings or roles. Detailed description of known technologies will be omitted if it is determined that the detailed description of the known technologies obscures the embodiments of the present specification. In addition, the accompanying drawings are merely intended to easily describe the embodiments of the present specification, but the spirit and technical scope of the present specification is not limited by the accompanying drawings. It should be understood that the present specification is not limited to specific disclosed embodiments, but includes all modifications, equivalents and substitutes included within the spirit and technical scope of the present disclosure.

Terms including ordinals such as “first” or “second” used herein may be used to describe various elements, but the elements are not limited by the terms. The terms are used only for the purpose of distinguishing one constituent element from another constituent element.

As used herein, the singular forms “a”, “an”, and “the” are intended to include the plural forms as well, unless the context clearly indicates otherwise.

It is to be understood that terms such as “including,” “having,” and other similar terms are intended to indicate the existence of the features, numbers, steps, actions, elements, components, or combinations thereof disclosed in the specification, and are not intended to preclude the possibility that one or more other features, numbers, steps, actions, elements, components, or combinations thereof may exist or may be added.

In addition, “unit” or “control unit” included in the names of the motor control unit (MCU) generally refer to a controller that controls a specific function and do not mean a generic function unit. Each controller unit may include a communication device configured to communicate with another control unit or a sensor in order to control a function assigned thereto, a memory configured to store an operating system, logic commands, and input and output information, and at least one processor configured to perform determination, calculation, and decision necessary to control the assigned function. A ‘terminal’ referred hereinafter may also have a configuration similar to the controller.

According to an embodiment of the present disclosure, an electrified vehicle and a battery control method of the electrified vehicle configured to convert a real state of charge (SOC) of a battery into a display SOC based on conditions such as a change in temperature of the battery and whether the battery is charged by an external power source, may be provided.

Particularly, in a vehicle according to an embodiment, a lower limit reference point may be determined according to a temperature of the battery and the real SOC of the battery, an upper limit reference point may be determined based on whether the battery is charged by the external power source and the real SOC. Furthermore, an inflection point may be determined based on whether the lower limit reference point is changed, and whether charging of the battery by the external power source is ended. In addition, a corresponding relationship between the real SOC and the display SOC may be determined based on the lower limit reference point, the upper limit reference point, and the inflection point. In addition, based on the corresponding relationship, the real SOC of the battery may be converted into the display SOC, and the display SOC may be output through an output device.

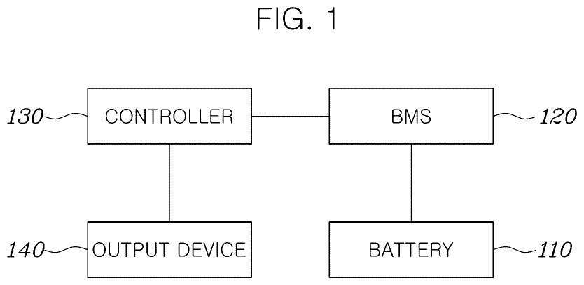

First, a configuration of a vehicle applicable to embodiments will be described with reference to FIG. 1.

FIG. 1 is a view illustrating an example of a configuration of an electrified vehicle applicable to embodiments.

At this time, it is assumed that the vehicle illustrated in FIG. 1 is an Electric Vehicle (EV). However, this is an example for convenience of description, and is applicable to an electrified vehicle in the form of a Hybrid Electric Vehicle (HEV) that is not an electric vehicle.

Referring to FIG. 1, the electrified vehicle according to an embodiment may include a battery 110, a battery management system (BMS) 120, a controller 130, and an output device 140. FIG. 1 is a view mainly illustrating components related to embodiments of the present disclosure, and more or less components may be included in an implementation of an actual electrified vehicle. Hereinafter, each component will be described in more detail.

The battery 110 may serve to store and supply an electric power required for driving the electric vehicle. Such a battery 110 may be a lithium-ion battery, a nickel-metal hydride battery (NiMH), a solid-state battery, a lithium polymer battery, and a lithium-sulfur battery. However, this is only an example, and a configuration capable of storing and supplying an electric power to a vehicle is also applicable and is not limited.

The BMS 120 may obtain status information of the battery 110 such as a voltage, a current, a SOC, a temperature, and a usable electric power of the battery, and may provide the status information to the controller 130 and other status information.

For example, the BMS 120 may measure the real SOC of the battery and may measure the temperature of the battery. In addition, the BMS 120 may determine whether the battery is charged by the external power source, and may measure a voltage and a current of the power source supplied from the outside.

The controller 130 may function as an upper-level controller that integrates and controls an overall function of the electric vehicle.

For example, the controller 130 may determine the lower limit reference point, the upper limit reference point, and the inflection point by using information about the battery received through the BMS 120. Specifically, based on the temperature of the battery and the real SOC of the battery provided from the BMS 120, the lower limit reference point defined by a preset display SOC lower limit value and a corresponding real SOC lower limit value may be determined. In addition, based on whether the battery 110 is charged by the external power source and the real SOC of the battery, the upper limit reference point defined by a preset display SOC upper limit value and a corresponding real SOC upper limit value may be determined. In addition, the inflection point may be determined based on the temperature of the battery and the real SOC of the battery, and the determined inflection point may be stored. The inflection point may be defined by the real SOC and the display SOC of the battery at the time when the inflection point is determined.

In addition, the controller 130 may determine the corresponding relationship between the real SOC of the battery and the display SOC based on the lower limit reference point, the upper limit reference point, and the inflection point. In addition, based on the corresponding relationship, the real SOC of the battery may be converted into the display SOC. In addition, the output device 140 may be controlled such that the converted display SOC is output through the output device 140.

At this time, a process of determining the lower limit reference point, the upper limit reference point, and the inflection point, and a process of determining the corresponding relationship based on the lower limit reference point, the upper limit reference point, and the inflection point and then converting the real SOC value of the battery to the display SOC value based on the corresponding relationship will be described later.

The output device 140 may output the display SOC by a control of the controller 130. The output device 140 may include a cluster, a head-up display (HUD), a display device, a speaker, and other components. However, this is an example, and is not necessarily limited to this configuration.

In addition, in the implementation of the output device 140, the output device 140 may be implemented as a function of an audio/video/navigation (AVN) system provided in the vehicle. However, this is an example, and is not necessarily limited to this configuration.

Hereinafter, a battery control method of the present disclosure will be described based on the configuration of the vehicle described above.

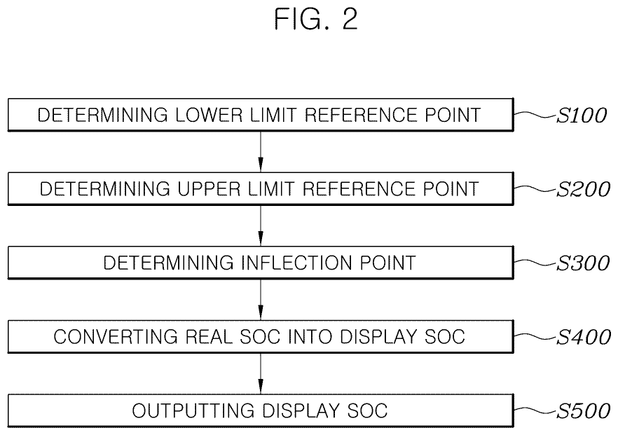

FIG. 2 is a flowchart illustrating a battery control method according to an embodiment of the present disclosure.

In the description below, it is assumed that the lower limit reference point is determined and then the upper limit reference point is determined in the vehicle. However, this is for convenience of description, and the upper limit reference point, the lower limit reference point, and the inflection point may be determined simultaneously. Furthermore, only a portion of the upper limit reference point, the lower limit reference point, and the inflection point may be determined, and there may be no limitation in the determination order of the upper limit reference point, the lower limit reference point, and the inflection point.

Referring to FIG. 2, the controller 130 may determine the lower limit reference point (S100).

As described above, the lower limit reference point may be defined by the preset display SOC lower limit value and the corresponding real SOC lower limit value.

For example, the controller 130 may determine the lower limit reference point defined by the preset display SOC lower limit value and the corresponding real SOC lower limit value.

Specifically, the preset display SOC lower limit value may be Y_{L} (for example, about 0%), and the corresponding real SOC lower limit value may be X_{L} (for example, about 5% to 20%). However, this is an example, and is not limited to this configuration.

For example, the controller 130 may determine the real SOC lower limit value based on the temperature of the battery and the real SOC of the battery. Specifically, any one of a plurality of real SOC lower limit values preset to correspond to different temperatures or different temperature ranges may be determined as the real SOC lower limit value.

For example, when the temperature of the battery is equal to or more than a preset first temperature, the controller 130 may determine the real SOC lower limit value as a preset first real SOC lower limit value.

When the temperature of the battery is equal to or less than the preset first temperature and is equal to or more than a preset second temperature, the controller 130 may determine the real SOC lower limit value as a preset second real SOC lower limit value.

When the temperature of the battery is equal to or less than the preset second temperature, the controller 130 may determine the real SOC lower limit value as a preset third real SOC lower limit value.

More specifically, the first temperature may be higher than the second temperature.

For example, the first temperature may be T₁ (for example, about −10 degrees Celsius), and the second temperature may be T₂ (for example, about −20 degrees Celsius). In addition, the preset first real SOC lower limit value may be X₁ (for example, about 5%), the preset second real SOC lower limit value may be X₂ (for example, about 10%), and the preset third real SOC lower limit value may be X₃ (for example, about 15%). However, this is only an example, and is not limited to this configuration.

For example, when the temperature of the battery is equal to or more than the first temperature, the controller 130 may determine the real SOC lower limit value as X₁ that is the first real SOC lower limit value. When the temperature of the battery is equal to or less than the first temperature and is equal to or more than the second temperature, the controller 130 may determine the real SOC lower limit value as X₂ that is the second real SOC lower limit value. When the temperature of the battery is equal to or less than the second temperature, the controller 130 may determine the real SOC lower limit value as X₃ that is the second real SOC lower limit value.

Meanwhile, when the real SOC lower limit value determined previously is the second real SOC lower limit value or the third real SOC lower limit value, the controller 130 may change the real SOC lower limit value to the first real SOC lower limit value only when the temperature of the battery increases and the temperature of the battery is equal to or more than the first temperature and only when the real SOC value of the battery is equal to or more than a preset real SOC reference value.

For example, the preset real SOC reference value may be X₄ (for example, about 20%). The temperature of the battery may be determined as equal to or more than the first temperature and equal to or less than the second temperature, and the real SOC lower limit value may be determined as the second real SOC lower limit value. Then, when the temperature of the battery increases equal to or more than the first temperature T₁ and the real SOC value of the battery increases equal to or more than the present real SOC reference value X₄, the controller 130 may newly determine the real SOC lower limit value of the lower limit reference point from the second real SOC lower limit value to the first real SOC lower limit value.

Meanwhile, the temperature of the battery 110 may be measured repeatedly, and may be measured repeatedly at a preset measurement time. In addition, when the vehicle is started, the temperature of the battery 110 may be measured after a preset stabilization time has elapsed. The reason for this may be to secure the stabilization time for temperature measurement.

The controller 130 may determine the upper limit reference point (S200).

As described above, the upper limit reference point may be defined by the preset display SOC upper limit value and the corresponding real SOC upper limit value.

For example, the controller 130 may determine the upper limit reference point defined by the preset display SOC upper limit value and the corresponding real SOC upper limit value.

Specifically, the preset display SOC upper limit value may be Y_{H} (for example, about 100%), and the corresponding real SOC upper limit value may be X_{H} (for example, about 90% to 100%).

For example, the controller 130 may determine the real SOC upper limit value of the upper limit reference point based on the real SOC of the battery, and a charging status of the battery by the external power source. Specifically, when the real SOC of the battery is discharged equal to or less than the real SOC lower limit value of the lower limit reference point, or when the battery is charged equal to or more than the real SOC upper limit value of the upper limit reference point or the battery enters a charging state by the external power source, the preset real SOC upper limit value may be newly determined as the real SOC upper limit value.

In addition, when a normal charging of the battery 110 is impossible, such as the inability to perform a Constant Voltage (CV) charging, the real SOC of the current battery may be determined as the real SOC upper limit value of the upper limit reference point.

In addition, the controller 130 may determine the inflection point (S300).

For example, the controller 130 may determine the inflection point based on at least one of a change in temperature of the battery and whether the battery is charged by the external power source.

For example, when the real SOC lower limit value of the lower limit reference point is changed due to a change in temperature of the battery, the controller 130 may determine and store a first inflection point defined by the real SOC and the display SOC of the battery at that time.

In addition, when charging of the battery by the external power source is started or ended, the controller 130 may determine and store a second inflection point defined by the real SOC and the display SOC of the battery at that time.

In addition, when the real SOC lower limit value is determined as the second real SOC lower limit value or the third real SOC lower limit value described above after the vehicle is started, the controller 130 may determine the corresponding relationship based on the lower limit reference point after the vehicle is started and a preset reference inflection point, and may convert the real SOC into the display SOC based on the corresponding relationship. Subsequently, the controller 130 may compare the size of the display SOC after the vehicle is started determined as described above with the size of the display SOC before the vehicle is started. When the display SOC determined after the vehicle is started is smaller than the display SOC before the vehicle is started, the controller 130 may determine and store the preset reference inflection point as a third inflection point.

For example, the preset reference inflection point may be defined by the display SOC and the corresponding real SOC. The display SOC of the preset reference inflection point may be X₅ (for example, about 15%), and the corresponding real SOC may be Y₅ (for example, about 20%). Meanwhile, the controller 130 may delete a stored inflection point.

For example, when the real SOC of the battery is equal to or less than the real SOC lower limit value of the lower limit reference point, the stored inflection point stored in situations such as updating (reprogramming) of a firmware of the controller 130 and a B+ interruption of an auxiliary battery (temporarily blocking a constant supply of a power to an electronic device) may be removed, and the controller 130 may remove the stored inflection point when the real SOC of the battery is equal to or more than the real SOC upper limit value of the upper limit reference point.

The controller 130 may determine the corresponding relationship between the real SOC and the display SOC, and may convert the real SOC to the display SOC based on the corresponding relationship (S400).

For example, the controller 130 may determine the corresponding relationship based on the upper limit reference point, the lower limit reference point, and the inflection point. For example, the corresponding relationship may be in the form of a linear function defined through the real SOC and the display SOC. In addition, the corresponding relationship may correspond to a line segment connecting the lower limit reference point and the upper limit reference point to each other in a graph in which a first axis corresponds to the real SOC and a second axis corresponds to the display SOC.

Subsequently, the controller 130 may convert the real SOC into the display SOC based on the corresponding relationship.

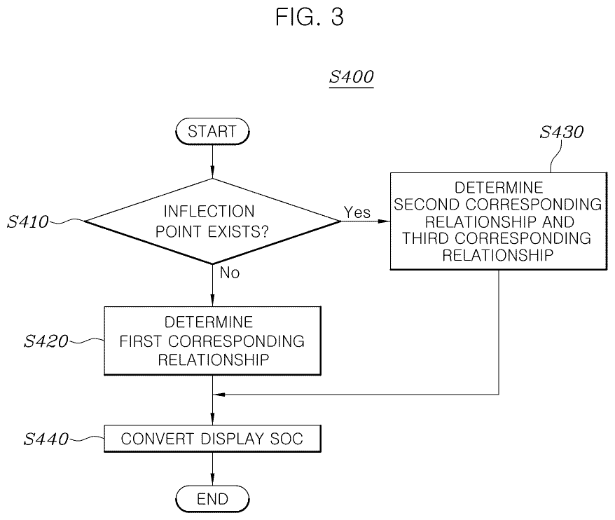

A detailed process of determining the corresponding relationship and converting the real SOC into the display SOC based on the corresponding relationship will be described later with reference to FIG. 3.

Subsequently, the output device 140 may output the converted display SOC (S500).

The controller 130 may control the output device 140 such that the display SOC is output through the output device 140. For example, the controller 130 may control at least one of a cluster, a head-up display (HUD), a display device, and a speaker that are included in the output device so that the display SOC is output.

Hereinafter, the process of determining the corresponding relationship between the real SOC value and the display SOC value of the battery control method of the present disclosure will be described with reference to FIG. 3.

Referring to FIG. 3, the controller 130 may determine whether the inflection point exists (S410).

When the inflection point does not exist, the controller 130 may determine a first corresponding relationship by using the following equation 1 (S420). At this time, the first corresponding relationship may be expressed as a linear function defined by the real SOC value and the display SOC value. In addition, the first corresponding relationship may be defined as a line segment connecting the lower limit reference point and the upper limit reference point to each other in a graph in which a first axis corresponds to the real SOC and a second axis corresponds to the display SOC.

$${Y}_{V} = ( {Y}_{{H}^{-}} {Y}_{L} / {X}_{{H}^{-}} {X}_{L} ) \times ( {X}_{{V}^{-}} {X}_{L} ) + {Y}_{L} \qquad [ Equation 1 ]$$

In Equation 1, Y_{H} refers to the display SOC upper limit value of the upper limit reference point, X_{H} refers to the real SOC upper limit value of the upper limit reference point, Y_{L} refers to the display SOC lower limit value of the lower limit reference point, X_{L} refers to the real SOC lower limit value of the lower limit reference point, Y_{V} refers to the converted display SOC, and X_{V} refers to the real SOC.

When the inflection point exists, the controller 130 may determine a second corresponding relationship and a third corresponding relationship by using the following equations 2 and 3 (S430).

That is, the corresponding relationship between the real SOC and the display SOC may be changed before and after the inflection point.

For example, when the real SOC of the battery is equal to or less than the real SOC of the inflection point, the controller 130 may determine the second corresponding relationship by using the equation 2 below. At this time, the second corresponding relationship may be expressed as a linear function defined by the real SOC value and the display SOC value. In addition, the second corresponding relationship may be defined as a line segment connecting the lower limit reference point and the inflection point to each other in a graph in which a first axis corresponds to the real SOC and a second axis corresponds to the display SOC.

$${Y}_{V} = ( {Y}_{{H}^{-}} {Y}_{L} / {X}_{{H}^{-}} {X}_{L} ) \times ( {X}_{{V}^{-}} {X}_{L} ) + {Y}_{L} \qquad [ Equation 2 ]$$

In Equation 2, Y_{L} refers to the display SOC lower limit value of the lower limit reference point, X_{L} refers to the real SOC lower limit value of the lower limit reference point, Y_{Z} refers to the display SOC at the inflection point, X_{Z} refers to the real SOC at the inflection point, Y_{V} refers to the converted display SOC, and X_{V} refers to the real SOC value of the battery.

In addition, when the real SOC of the battery is equal to or more than the real SOC of the inflection point, the controller 130 may determine the third corresponding relationship by using the equation 3 below. At this time, the third corresponding relationship may be expressed as a linear function defined by the real SOC value and the display SOC value. In addition, the third corresponding relationship may be defined as a line segment connecting the inflection point and the upper limit reference point to each other in a graph in which a first axis corresponds to the real SOC and a second axis corresponds to the display SOC.

$${Y}_{V} = ( {Y}_{{H}^{-}} {Y}_{L} / {X}_{{H}^{-}} {X}_{L} ) \times ( {X}_{{V}^{-}} {X}_{L} ) + {Y}_{L} \qquad [ Equation 3 ]$$

In Equation 3, Y_{H} refers to the display SOC upper limit value of the upper limit reference point, X_{H} refers to the real SOC upper limit value of the upper limit reference point, Y_{Z} refers to the display SOC at the inflection point, X_{Z} refers to the real SOC at the inflection point, Y_{V} refers to the converted display SOC, and X_{V} refers to the real SOC value of the battery.

The controller 130 may convert the real SOC into the display SOC based on the determined corresponding relationship (S440).

When the inflection point does not exist, the real SOC of the battery may be converted into the display SOC based on the first corresponding relationship.

When the inflection point exists and the real SOC of the battery is equal to or less than the real SOC of the inflection point, the real SOC may be converted into the display SOC based on the second corresponding relationship.

When the inflection point exists and the real SOC of the battery is equal to or more than the real SOC of the inflection point, the real SOC may be converted into the display SOC based on the third corresponding relationship.

Meanwhile, when it is determined that the battery 110 is fully charged, the display SOC may be increased at a preset speed.

For example, when more than 40 minutes have elapsed after reaching CV (Constant Voltage), or when the voltage is maintained for more than 10 seconds after exceeding CV, the displayed SOC value can be increased at a constant speed.

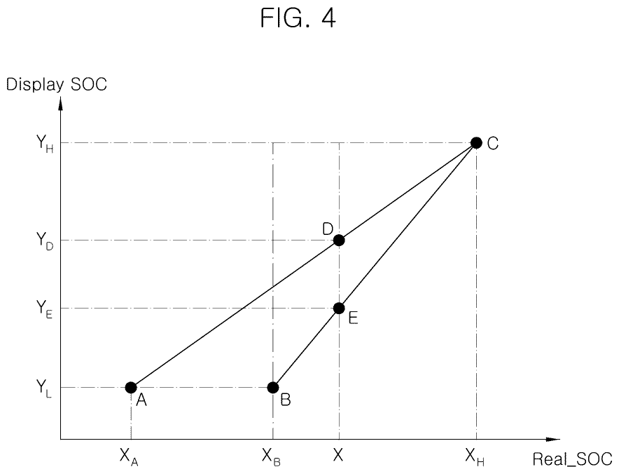

Hereinafter, examples of converting the real SOC into the display SOC according to an embodiment of the present disclosure will be described with reference to FIGS. 4, 5, 6, and 7.

For convenience of description, a graph in which a first axis (a horizontal axis) corresponds to the real SOC and a second axis (a vertical axis) corresponds to the display SOC value is shown. The first, second, and third corresponding relationships defined as linear functions defined through the real SOC and the display SOC may be expressed in the form of linear functions on the coordinate plane. Furthermore, the first corresponding relationship may be expressed as a line segment passing the lower limit reference point and the upper limit reference point, the second corresponding relationship may be expressed as a line segment passing the lower limit reference point and the inflection point, and the third corresponding relationship may be expressed as a line segment passing the inflection point and the upper limit reference point.

Meanwhile, the lower limit reference point, the upper limit reference point, and the inflection point may be expressed as points on the coordinate plane in which the first axis (the horizontal axis) corresponds to the real SOC and the second axis (the vertical axis) corresponds to the display SOC value.

FIG. 4 is an example in which the inflection point does not exist.

In FIG. 4, it is assumed that driving of the vehicle is started after the battery is fully charged to the preset real SOC upper limit value (point C) and then the battery is discharged to point D.

The controller 130 may determine the lower limit reference point and the upper limit reference point, and may determine the corresponding relationship between the real SOC and the display SOC based on the lower limit reference point and the upper limit reference point.

For example, the controller 130 may determine point A or point B as the lower limit reference point based on the temperature of the battery 110 and may determine point C as the upper limit reference point.

For example, the real SOC and the display SOC at point A or point B may be determined as the real SOC (X_{L}) and the display SOC (Y_{L}) of the lower limit reference point, and the real SOC and the display SOC at point C may be determined as the real SOC (X_{H}) and the display SOC (Y_{H}) of the upper limit reference point.

For example, X_{A} and X_{B} may be any one of a plurality of real SOC lower limit values preset to correspond to different temperatures or different temperature ranges and, specifically, X_{A} may be X₁ that is the first real SOC lower limit value and X_{B} may be X₂ that is the second real SOC lower limit value.

For example, the corresponding relationship may be a linear function defined through the real SOC and the display SOC determined based on the aforementioned equation 1. The corresponding relationship may be expressed as the line segment AC or the line segment BC passing through the lower limit reference point (point A or point B) and the upper limit reference point (point C).

For example, when the temperature of the battery is equal to or more than the first temperature, the corresponding relationship may be expressed as the line segment AC passing through the lower limit reference point (point A) and the upper limit reference point (point C). The real SOC value of the battery at point D is X %, and the display SOC value may be converted into YD % by the corresponding relationship.

For example, when the temperature of the battery is equal to or less than the first temperature and equal to or more than the second temperature, the corresponding relationship may be expressed as the line segment BC passing through the lower limit reference point (point B) and the upper limit reference point (point C). For example, when the real SOC value of the battery at point E is X %, and the display SOC value may be converted into YE % by the corresponding relationship.

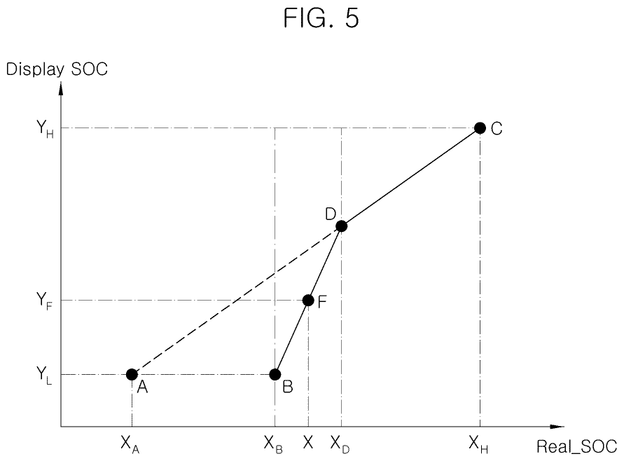

In FIG. 5, it is assumed that while the battery is discharged by driving the vehicle from point C in which charging of the battery is finished, the temperature of the battery is changed from the temperature equal to or more than the first temperature to the temperature equal to or less than the first temperature and equal to or more than the second temperature at point D, and then the lower limit reference point is changed from point A to point B.

In the process of discharging the battery from point C to point D, the corresponding relationship between the real SOC and the display SOC may be the third corresponding relationship determined based on the aforementioned equation 3.

However, in a situation in which the battery is discharged while the display SOC is output according to the third corresponding relationship, when the temperature of the battery is changed as the assumption described above at the time when the real SOC reaches point D, the controller 130 may change the lower limit reference point to point B.

In addition, the inflection point (point D) defined through the real SOC and the display SOC of the battery at the corresponding time may be determined.

When point D is determined as the inflection point, the controller 130 may determine the second corresponding relationship between the real SOC and the display SOC based on the aforementioned equation 2 for the section between the inflection point (point D) and the changed lower limit reference point (point B).

When the real SOC of the battery decreases compared to the real SOC (XD) corresponding to the inflection point due to the continuous discharge, the display SOC follows the second corresponding relationship. When the real SOC becomes higher than the real SOC (XD) corresponding to the inflection point due to regenerative braking during driving, the display SOC follows the third corresponding relationship again.

As described above, the corresponding relationship between the real SOC and the display SOC may be changed before and after the inflection point. In addition, the transition of the corresponding relationship for determining the display SOC based on such an inflection point (point D) may be maintained until the inflection point (point D) is deleted.

For example, the real SOC value of the battery at point F is X %, and the display SOC value may be converted into YF % by the corresponding relationship.

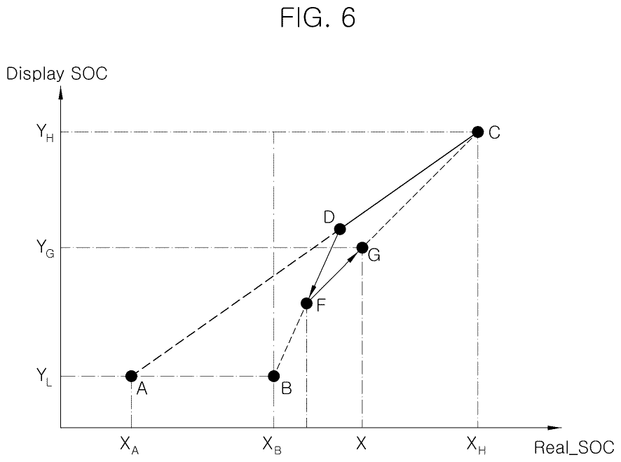

In FIG. 6, it is assumed that while the battery is discharged by driving the vehicle from point C in which the battery is charged, the temperature of the battery is changed from the temperature equal to or more than the first temperature to the temperature equal to or less than the first temperature and the temperature equal to or more than the second temperature, the lower limit reference point is changed from point A to point B and the inflection point (point D) defined through the real SOC and the display SOC of the battery at the corresponding time is determined, an engine of the vehicle is turned-off during discharging the battery by continuously driving the vehicle, and then the battery is charged (point F) by the external power source.

The corresponding relationship between the real SOC and the display SOC in the process of discharging the battery from point C to point D and in the process of discharging the battery from point D to point F is same as the description in FIG. 5.

In the process of charging the battery from point F to point G, which is a situation in which the battery is charged by the external power source, the controller 130 may set the inflection point (point F) at the time when charging by the external power source starts, and may determine the corresponding relationship between the real SOC and the display SOC based on the inflection point and the upper limit reference point. The corresponding relationship may be expressed as the line segment FC passing through the inflection point (point F) and the upper limit reference point (point C). In addition, as described above, since charging by the external power source occurs, the inflection point (point D) set in FIG. 5 may be deleted.

For example, when the real SOC value of the battery at point G is X %, the display SOC value may be converted into Y_{G}% through the corresponding relationship.

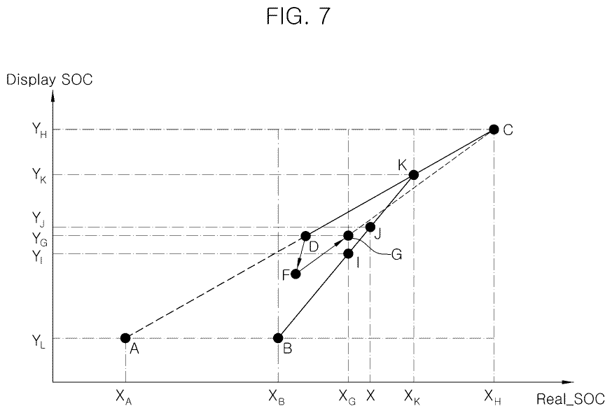

In FIG. 7, it is assumed that the vehicle is started at point G while the battery is charged from point F by the external power source following the situation illustrated in FIG. 6.

The corresponding relationship between the real SOC and the display SOC in the process of discharging the battery from point C to point D, in the process of discharging the battery from point D to point F, and in the process of charging the battery from point F to point G is same as the description in FIG. 7.

When the vehicle is started, the controller 130 may determine the corresponding relationship based on the lower limit reference point (point B) after the vehicle is started and the preset reference inflection point (point K).

For example, X_{K} and Y_{K} may be the real SOC and the display SOC of the reference inflection point and, specifically, X_{K} may be X₅ that is the real SOC of the reference inflection point, and Y_{K} may be Y₅ that is the display SOC of the reference inflection point.

The corresponding relationship may be expressed as the line segment BK based on the lower limit reference point (point B) and the preset reference inflection point (point K), and the real SOC (X_{G}) may be converted into the display SOC (point I, Y_{I}) based on the corresponding relationship.

Subsequently, the controller 130 may compare the display SOC (point G, Y_{G}) determined before the vehicle is started with the display SOC (point I, Y_{I}) determined after the vehicle is started. At this time, since the display SOC (point I, Y_{I}) determined after the vehicle is started is lower than the display SOC (point G, Y_{G}) before the vehicle is started, the controller 130 may determine the reference inflection point (point K) as the inflection point, and may determine the corresponding relationship between the real SOC and the display SOC based on the determined inflection point (point K), the upper limit reference point (point C), and the lower limit reference point (point B).

For example, when the real SOC value of the battery at point J is X %, the display SOC value may be converted into Y_{J}% through the corresponding relationship.

The present disclosure described above may be embodied as a computer-readable code on a medium in which a program is recorded. A computer-readable medium includes all types of recording devices in which data readable by a computer system is stored. Examples of the computer-readable medium include a Hard Disk Drive (HDD), a Solid-State Drive (SSD), a Silicon Disk Drive (SDD), a Read-Only Memory (ROM), a Random-Access Memory (RAM), a CD-ROM, a magnetic tape, a floppy disk, an optical data storage device, and other mediums. The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the present disclosure and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A battery control method comprising:
determining a lower limit reference point based on a temperature of a battery or a real state of charge (SOC) of the battery, the lower limit reference point being defined by a preset display SOC lower limit value and a real SOC lower limit value corresponding to the preset display SOC lower limit value;
determining an upper limit reference point defined by a preset display SOC upper limit value and a real SOC upper limit value corresponding to the preset display SOC upper limit value; and
determining a corresponding relationship based on the lower limit reference point and the upper limit reference point and converting the real SOC to a display SOC.

2. The battery control method of claim 1, wherein the determining the lower limit reference point comprises determining the lower limit reference point by determining any one of a plurality of real SOC lower limit values corresponding to the temperature of the battery as the real SOC lower limit value, the plurality of real SOC lower limit values being preset so as to correspond to different temperatures or temperature ranges.

3. The battery control method of claim 2, wherein the determining the lower limit reference point comprises determining the real SOC lower limit value as a first real SOC lower limit value when the temperature of the battery is equal to or more than a preset first temperature, as a second real SOC lower limit value when the temperature of the battery is equal to or less than the first temperature and equal to or more than a second temperature, and as a third real SOC lower limit value when the temperature of the battery is equal to or less than the second temperature, and
the first temperature is higher than the second temperature.

4. The battery control method of claim 1, wherein, in the determining the upper limit reference point, the real SOC upper limit value is determined based on the real SOC of the battery and whether the battery is charged by an external power source.

5. The battery control method of claim 1, further comprising determining an inflection point based on a change in temperature of the battery and whether the battery is charged by an external power source,
wherein the inflection point is defined by the real SOC and the display SOC of the battery at a time when the inflection point is determined, and the corresponding relationship is changed before and after the inflection point.

6. The battery control method of claim 5, wherein the determining the inflection point comprises determining the inflection point at the time when the temperature of the battery is changed and the real SOC lower limit value is changed and at the time when charging of the battery by the external power source is started or ended.

7. The battery control method of claim 5, wherein the determining the inflection point comprises deleting a stored inflection point when the real SOC of the battery is equal to or less than the real SOC lower limit value of the lower limit reference point or when the real SOC of the battery is equal to or more than the real SOC upper limit value of the upper limit reference point.

8. The battery control method of claim 1, wherein the converting the real SOC to the display SOC comprises determining the corresponding relationship based on the lower limit reference point defined by the display SOC lower limit value and the corresponding real SOC lower limit value and based on the upper limit reference point defined by the display SOC upper limit value and the corresponding real SOC upper limit value.

9. The battery control method of claim 8, wherein the converting the real SOC to the display SOC comprises determining a first corresponding relationship through:
$${Y}_{V} = ( {Y}_{{H}^{-}} {Y}_{L} / {X}_{{H}^{-}} {X}_{L} ) \times ( {X}_{{V}^{-}} {X}_{L} ) + {Y}_{L} ;$$
where Y_{H} refers to the display SOC upper limit value of the upper limit reference point, X_{H} refers to the real SOC upper limit value of the upper limit reference point, Y_{L} refers to the display SOC lower limit value of the lower limit reference point, X_{L} refers to the real SOC lower limit value of the lower limit reference point, Y_{V} refers to the display SOC that is converted, and X_{V} refers to the real SOC of the battery.

10. The battery control method of claim 5, wherein the converting the real SOC to the display SOC comprises determining the corresponding relationship based on the lower limit reference point defined by the display SOC lower limit value and the corresponding real SOC lower limit value, the upper limit reference point defined by the display SOC upper limit value and the corresponding real SOC upper limit value, and the inflection point.

11. The battery control method of claim 10, wherein the converting the real SOC to the display SOC comprises converting the real SOC of the battery to the display SOC through a second corresponding relationship when the real SOC of the battery is equal to or less than the real SOC at the inflection point, and through a third corresponding relationship when the real SOC of the battery is equal to or more than the real SOC at the inflection point.

12. The battery control method of claim 11, wherein the converting the real SOC to the display SOC comprises determining the second corresponding relationship through:
$${Y}_{V} = ( {Y}_{{H}^{-}} {Y}_{L} / {X}_{{H}^{-}} {X}_{L} ) \times ( {X}_{{V}^{-}} {X}_{L} ) + {Y}_{L} ;$$
where Y_{L} refers to the display SOC lower limit value of the lower limit reference point, X_{L} refers to the real SOC lower limit value of the lower limit reference point, Y_{Z} refers to the display SOC at the inflection point, X_{Z} refers to the real SOC at the inflection point, Y_{V} refers to the display SOC that is converted, and X_{V} refers to the real SOC of the battery.

13. The battery control method of claim 11, wherein the converting the real SOC to the display SOC comprises determining the third corresponding relationship through:
$$YV = ( YH - YL / XH - XL ) \times ( XV - XL ) + YL ;$$
where YH refers to the display SOC upper limit value of the upper limit reference point, XH refers to the real SOC upper limit value of the upper limit reference point, YZ refers to the display SOC at the inflection point, XZ refers to the real SOC at the inflection point, YV refers to the display SOC that is converted, and XV refers to the real SOC of the battery.

14. The battery control method of claim 1, further comprising outputting the display SOC that is determined.

15. A vehicle comprising:
a battery configured to store electric power for driving the vehicle;
a battery management system (BMS) configured to acquire status information of the battery, the status information including voltage, current, SOC, temperature, and usable power; and
a controller configured to determine a lower limit reference point based on a temperature of the battery and a real state of charge (SOC) of the battery in which the lower limit reference point is defined by a preset display SOC lower limit value and a real SOC lower limit value corresponding to the preset display SOC lower limit value, configured to determine an upper limit reference point defined by a preset display SOC upper limit value and a real SOC upper limit value corresponding to the preset display SOC upper limit value, configured to determine a corresponding relationship based on the lower limit reference point and the upper limit reference point, and configured to convert the real SOC into a display SOC.

16. The vehicle of claim 15, wherein the controller is configured to determine the corresponding relationship based on the lower limit reference point defined by the display SOC lower limit value and the corresponding real SOC lower limit value and based on the upper limit reference point defined by the display SOC upper limit value and the corresponding real SOC upper limit value.

17. The vehicle of claim 15, wherein the controller is configured to determine an inflection point based on a change in temperature of the battery and whether the battery is charged by an external power source, the inflection point is defined by the real SOC and the display SOC of the battery at a time when the inflection point is determined, and the corresponding relationship is changed before and after the inflection point.

18. The vehicle of claim 17, wherein the controller is configured to determine the corresponding relationship based on the lower limit reference point defined by the display SOC lower limit value and the corresponding real SOC lower limit value, the upper limit reference point defined by the display SOC upper limit value and the corresponding real SOC upper limit value, and the inflection point.

19. The vehicle of claim 15, further comprising an output device configured to output the display SOC.

20. The vehicle of claim 19, wherein the output device comprises at least one of a cluster, a Head-Up Display (HUD), a display device, and a speaker.
